(19) United States
(12) Patent Application Publication
(10) Pub. No.: US 2025/0336823 A1
(43) Pub. Date: Oct. 30, 2025

(54) BACKSIDE POWER DELIVERY IN 3D DIE

(71) Applicant: INTERNATIONAL BUSINESS MACHINES CORPORATION, ARMONK, NY (US)

(72) Inventors: Mukta Ghate Farooq, HOPEWELL JCT, NY (US); Hemanth Jagannathan, Niskayuna, NY (US)

(21) Appl. No.: 18/644,856

(22) Filed: Apr. 24, 2024

(51) Int. Cl. H01L 23/528; H01L 21/768; H01L 23/48

(52) U.S. Cl. CPC H01L 23/5286; H01L 21/76898; H01L 23/481

(57) ABSTRACT

A semiconductor device includes a wafer having a frontside, a backside, and front end of line (FEOL) devices arranged on the frontside. The semiconductor device includes a first dielectric material coupled to the frontside and including frontside wiring electrically connected to the FEOL devices. The semiconductor device includes a second dielectric material coupled to the backside and including backside wiring electrically connected to the FEOL devices. The semiconductor device includes a first and second vias extending through the first dielectric material and electrically connected with the backside wiring such that a first power delivery pathway delivers power to a first FEOL device through the first via and the backside wiring and a second power delivery pathway delivers power to a second FEOL device through the second via and the backside wiring. The first power delivery pathway is shorter than the second power delivery pathway.

### BACKGROUND

The present disclosure relates to the semiconductor device fields. In particular, the present disclosure relates to semiconductor devices that utilize backside power delivery.

Front end of line (FEOL) refers to the individual devices of an integrated circuit (IC), such as transistors, capacitors, resistors, etc., that are interconnected to enable the functionality of the IC device. Back end of line (BEOL) refers to the interconnects that provide power and signal to the FEOL devices with wiring formed by metallization layers. Frontside refers to structures arranged on the side of the silicon wafer that originally faces upwardly during IC fabrication processes. In contrast, backside refers to structures arranged on the side of the silicon wafer that originally faces downwardly during IC fabrication processes. Backside power delivery utilizes the BEOL to supply power from the backside of the IC device to the FEOL.

### SUMMARY

Embodiments of the present disclosure include a semiconductor device. The semiconductor device includes a wafer having a frontside and a backside and a plurality of front end of line devices arranged on the frontside. The semiconductor device further includes a first dielectric material coupled to the frontside of the wafer and including frontside wiring embedded therein that is electrically connected to the front end of line devices. The semiconductor device further includes a second dielectric material coupled to the backside of the wafer and including backside wiring embedded therein that is electrically connected to the front end of line devices. The semiconductor device further includes a first via extending through the first dielectric material and electrically connected with the backside wiring such that a first power delivery pathway delivers power to a first front end of line device through the first via and the backside wiring. The semiconductor device further includes a second via extending through the first dielectric material and electrically connected with the backside wiring such that a second power delivery pathway delivers power to a second front end of line device through the second via and the backside wiring. The first power delivery pathway is shorter than the second power delivery pathway.

Additional embodiments of the present disclosure include a semiconductor device. The semiconductor device includes a wafer having a frontside and a backside and a plurality of front end of line devices arranged on the frontside. The semiconductor device further includes a first dielectric material coupled to the frontside of the wafer and including frontside wiring embedded therein that is electrically connected to the front end of line devices. The semiconductor device further includes a second dielectric material coupled to the backside of the wafer and including backside wiring embedded therein that is electrically connected to the front end of line devices. The semiconductor device further includes a first via extending through the first dielectric material and electrically connected with the backside wiring. The semiconductor device further includes a second via extending through the first dielectric material, the wafer, and the second dielectric material. The first via contacts the backside wiring nearer to the first dielectric material than does the second via.

Additional embodiments of the present disclosure include a method of forming a semiconductor device. The method includes forming frontside wiring in a first dielectric material on a frontside of a wafer such that the frontside wiring is electrically connected to front end of line devices on the frontside of the wafer. The method further includes thinning the wafer from a backside of the wafer. The method further includes forming backside wiring in a second dielectric material on the backside of the thinned wafer such that the backside wiring is electrically connected to the front end of line devices. The method further includes forming a first via through the first dielectric material and electrically connected with the backside wiring.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a cross-sectional schematic view of a semiconductor device configured to enable backside power delivery to a front end of line device in a three-dimensional die, in accordance with embodiments of the present disclosure.

FIG. 2 illustrates a cross-sectional schematic view of a semiconductor device configured to enable backside power delivery to a front end of line device in a three-dimensional die, in accordance with embodiments of the present disclosure.

FIG. 3 illustrates a flowchart of a method for forming a semiconductor device configured to enable backside power delivery to a front end of line device in a three-dimensional die, in accordance with embodiments of the present disclosure.

FIG. 4A illustrates a cross-sectional schematic view of a semiconductor device following the performance of a portion of the method of FIG. 3, in accordance with embodiments of the present disclosure.

FIG. 4B illustrates a cross-sectional schematic view of a semiconductor device following the performance of a portion of the method of FIG. 3, in accordance with embodiments of the present disclosure.

FIG. 4C illustrates a cross-sectional schematic view of a semiconductor device following the performance of a portion of the method of FIG. 3, in accordance with embodiments of the present disclosure.

FIG. 4D illustrates a cross-sectional schematic view of a semiconductor device following the performance of a portion of the method of FIG. 3, in accordance with embodiments of the present disclosure.

FIG. 4E illustrates a cross-sectional schematic view of a semiconductor device following the performance of a portion of the method of FIG. 3, in accordance with embodiments of the present disclosure.

FIG. 4F illustrates a cross-sectional schematic view of a semiconductor device following the performance of a portion of the method of FIG. 3, in accordance with embodiments of the present disclosure.

FIG. 4G illustrates a cross-sectional schematic view of a semiconductor device following the performance of a portion of the method of FIG. 3, in accordance with embodiments of the present disclosure.

FIG. 4H illustrates a cross-sectional schematic view of a semiconductor device following the performance of a portion of the method of FIG. 3, in accordance with embodiments of the present disclosure.

FIG. 4I illustrates a cross-sectional schematic view of a semiconductor device following the performance of a portion of the method of FIG. 3, in accordance with embodiments of the present disclosure.

FIG. 4J illustrates a cross-sectional schematic view of a semiconductor device following the performance of a portion of the method of FIG. 3, in accordance with embodiments of the present disclosure.

### DETAILED DESCRIPTION

According to an aspect of the present disclosure, there is provided a semiconductor device. The semiconductor device includes a wafer having a frontside and a backside and a plurality of front end of line devices arranged on the frontside. The semiconductor device further includes a first dielectric material coupled to the frontside of the wafer and including frontside wiring embedded therein that is electrically connected to the front end of line devices. The semiconductor device further includes a second dielectric material coupled to the backside of the wafer and including backside wiring embedded therein that is electrically connected to the front end of line devices. The semiconductor device further includes a first via extending through the first dielectric material and electrically connected with the backside wiring such that a first power delivery pathway delivers power to a first front end of line device through the first via and the backside wiring. The semiconductor device further includes a second via extending through the first dielectric material and electrically connected with the backside wiring such that a second power delivery pathway delivers power to a second front end of line device through the second via and the backside wiring. The first power delivery pathway is shorter than the second power delivery pathway. By providing a shortened power delivery pathway for the device, voltage loss is reduced, improving the energy efficiency of the device.

In embodiments, a lowermost surface of the first via is substantially coplanar with a lowermost surface of the first dielectric material. Such embodiments enable electrical connection between the first via and a power source external to the semiconductor device through the lowermost surface of the first via.

In embodiments, an uppermost surface of the first via is substantially coplanar with an uppermost surface of the first dielectric material. Such embodiments shorten the power delivery pathway for the device by enabling power delivery through the uppermost surface of the first via to a height in the device that is close to the front end of line devices.

In embodiments, the uppermost surface of the first via is in direct contact with the frontside of the wafer. Such embodiments shorten the power delivery pathway for the device by enabling power delivery through the uppermost surface of the first via directly to the wafer that includes the front end of line devices.

In embodiments, the first via extends through the wafer and the second dielectric material and an uppermost surface of the first via is substantially coplanar with an uppermost surface of the second dielectric material. Such embodiments enable the shortened power delivery pathway for the device while also maintaining the electrical contact of the first via with connection features which electrically connect the device to other semiconductor devices in the IC.

In embodiments, a side surface of the first via is substantially perpendicular to the uppermost surface of the first via and the side surface is in direct contact with the backside wiring. Such embodiments enable power delivery through the side surface of the first via directly to the backside wiring that is connected to the front end of line devices while maintaining enablement of electrical contact of the first via with connection features which electrically connect the device to other semiconductor devices in the IC.

In embodiments, the second via extends through the wafer and the second dielectric material. Such embodiments enable the semiconductor device to support a shortened power delivery pathway through the first via while also enabling the same device to continue to support electrical connection with connection features which electrically connect the device to other semiconductor devices in the IC.

In embodiments, a lowermost surface of the second via is substantially coplanar with a lowermost surface of the first dielectric material, and an uppermost surface of the second via is substantially coplanar with an uppermost surface of the second dielectric material. Such embodiments facilitate efficient fabrication processes for forming the second via to enable power delivery from the backside of the device to the frontside of the device, including to other semiconductor devices in the IC.

In embodiments, the first power delivery pathway does not extend to the uppermost surface of the second dielectric material. Such embodiments enable improved energy efficiency for the delivery of power to front end of line devices through the first power delivery pathway without requiring the first power delivery pathway to pass through the entire thickness of the second dielectric material.

According to an aspect of the present disclosure, there is provided a semiconductor device. The semiconductor device includes a wafer having a frontside and a backside and a plurality of front end of line devices arranged on the frontside. The semiconductor device further includes a first dielectric material coupled to the frontside of the wafer and including frontside wiring embedded therein that is electrically connected to the front end of line devices. The semiconductor device further includes a second dielectric material coupled to the backside of the wafer and including backside wiring embedded therein that is electrically connected to the front end of line devices. The semiconductor device further includes a first via extending through the first dielectric material and electrically connected with the backside wiring. The semiconductor device further includes a second via extending through the first dielectric material, the wafer, and the second dielectric material. The first via contacts the backside wiring nearer to the first dielectric material than does the second via. By providing a first via that contacts the backside wiring nearer to the first dielectric material than does the second via, the semiconductor device enables improved energy efficiency for the delivery of power to front end of line devices through the first via while maintaining the efficiency of the delivery of power to other semiconductor devices in the IC through the second via.

In embodiments, the semiconductor device further includes a connection feature arranged on an uppermost surface of the second dielectric material and electrically connected to the second via and to the backside wiring. Such embodiments enable backside power delivery through the second via to the connection feature and to the front end of line devices.

In embodiments, a first power delivery pathway delivers power to a first front end of line device through the first via and the backside wiring, a second power delivery pathway delivers power to a second front end of line device through the second via, the connection feature, and the backside wiring, and the first power delivery pathway is shorter than the second power delivery pathway. Such embodiments enable improved energy efficiency for the delivery of power to front end of line devices through the first power delivery pathway while maintaining the efficiency of the delivery of power to other semiconductor devices in the IC through the second power delivery pathway.

In embodiments, an uppermost surface of the first via is in direct contact with the wafer. Such embodiments shorten the power delivery pathway for the device by enabling power delivery through the uppermost surface of the first via directly to the wafer that includes the front end of line devices.

In embodiments, an uppermost surface of the first via is substantially coplanar with an uppermost surface of the second dielectric material. Such embodiments shorten the power delivery pathway for the device by enabling power delivery through the uppermost surface of the first via to a height in the device that is close to the front end of line devices.

In embodiments, a side surface of the first via is substantially perpendicular to the uppermost surface of the first via, and the side surface is in direct contact with the backside wiring. Such embodiments enable power delivery through the side surface of the first via directly to the backside wiring that is connected to the front end of line devices while maintaining enablement of electrical contact of the first via with connection features which electrically connect the device to other semiconductor devices in the IC.

According to an aspect of the present disclosure, there is provided a method of forming a semiconductor device. The method includes forming frontside wiring in a first dielectric material on a frontside of a wafer such that the frontside wiring is electrically connected to front end of line devices on the frontside of the wafer. The method further includes thinning the wafer from a backside of the wafer. The method further includes forming backside wiring in a second dielectric material on the backside of the thinned wafer such that the backside wiring is electrically connected to the front end of line devices. The method further includes forming a first via through the first dielectric material and electrically connected with the backside wiring. By forming the first via through the first dielectric material and electrically connected with the backside wiring, the method enables the delivery of power from the backside of the device to front end of line devices on the wafer without having to pass through the entire thickness of the second dielectric material. This shortens the power delivery pathway for the device, which reduces voltage loss, improving the energy efficiency of the device.

In embodiments, forming the first via includes forming the first via such that an uppermost surface of the first via is substantially coplanar with the frontside of the wafer, and the first via is formed before forming the backside wiring. In such embodiments, the method enables a shortened power delivery pathway for the device by enabling power delivery through the uppermost surface of the first via directly to the wafer that includes the front end of line devices.

In embodiments, forming the first via includes forming the first via such that an uppermost surface of the first via is substantially coplanar with an uppermost surface of the second dielectric material and such that a side surface of the first via is substantially perpendicular to the uppermost surface of the first via and is in direct contact with the backside wiring, and the first via is formed after forming the backside wiring. In such embodiments, the method enables power delivery through the side surface of the first via directly to the backside wiring that is connected to the front end of line devices while maintaining enablement of electrical contact of the first via with connection features which electrically connect the device to other semiconductor devices in the IC.

In embodiments, the method further includes forming a second via through the first dielectric material, the wafer, and the second dielectric material such that the second via is not in direct contact with the backside wiring. In such embodiments, the method enables the formation of a semiconductor device to support a shortened power delivery pathway through the first via while also enabling the same device to continue to support electrical connection with connection features which electrically connect the device to other semiconductor devices in the IC.

In embodiments, the method further includes forming a connection feature in direct contact with the second via and with the backside wiring. In such embodiments, the method enables backside power delivery through the second via to the connection feature and to the front end of line devices.

Aspects of the present disclosure relate generally to the semiconductor fields. In particular, the present disclosure relates to the use of backside power delivery in IC devices. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, front end of line (FEOL) refers to the individual devices of an integrated circuit (IC), such as transistors, capacitors, resistors, etc., that are interconnected to enable the functionality of the IC device. Back end of line (BEOL) refers to the interconnects that provide power and signal to the FEOL devices with wiring formed by metallization layers. Frontside refers to structures arranged on the side of the silicon wafer that originally faces upwardly during IC fabrication processes. In contrast, backside refers to structures arranged on the side of the silicon wafer that originally faces downwardly during IC fabrication processes. A backside power delivery network (BSPDN) refers to backside power delivery arranged on the backside of the IC device and that cooperates with the BEOL to supply power from the backside of the IC device to the FEOL.

One advantage of using a BSPDN for power delivery is that it allows the BEOL interconnections to be split between the frontside and the backside of the device. Typically, the backside BEOL is then utilized for power delivery to the FEOL and the frontside BEOL is utilized for signal delivery to the FEOL. Splitting the BEOL in this manner to utilize the frontside BEOL for signal delivery enables lower congestion of signal wiring between FEOL devices. Additionally, splitting the BEOL in this manner to utilize the backside BEOL for power delivery enables direct delivery of power from the package to FEOL devices with lower voltage loss, thus improving the efficiency of the IC device.

One existing strategy for providing power to three-dimensional dies that include BSPDN includes arranging a top die, which could be a memory die like a static random-access memory (SRAM), on top of a three-dimensional intermediate die, which could be a logic die and which includes a BSPDN, and connecting the two dies, for example by soldering using bumps or by copper hybrid bonding. Such arrangements can be particularly useful, for example, in artificial intelligence (AI) hardware applications. In such arrangements, the power is supplied to the devices of the intermediate die by through silicon vias (TSVs) that are connected to the packaging substrate by lower solder bumps. However, such arrangements suffer from undesirable voltage loss as the power travels from the packaging substrate, through the lower solder bumps, through the TSVs, to the top of the intermediate die, and then back down through the backside BEOL wiring to the device.

Embodiments of the present disclosure may enable more efficient power delivery in a three-dimensional die including a BSPDN while avoiding problematic voltage loss by shortening the pathway of the power delivery to the devices in such arrangements. More specifically, embodiments of the present disclosure may improve the efficiency of delivering power to the devices in a three-dimension die having a BSPDN by arranging the backside BEOL wiring such that a TSV contacts the backside BEOL wiring more deeply in the three-dimensional die. Such embodiments eliminate the need for the power to travel all the way to the uppermost surface of the three-dimensional die in order to travel back down to the devices.

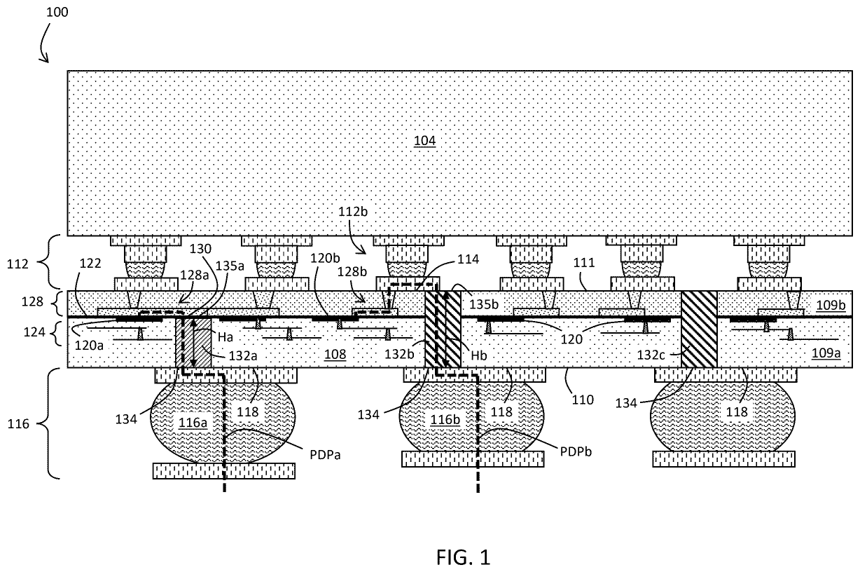

FIG. 1 depicts an example semiconductor device 100 that is configured to enable backside power delivery to a front end of line device in a three-dimensional die. In accordance with embodiments of the present disclosure, the semiconductor device 100 includes a top die 104, an intermediate die 108, and a series of connection features 112 configured to physically and electrically connect the top die 104 and the intermediate die 108. In accordance with at least one embodiment of the present disclosure, the top die 104 can be a memory die. For example, the top die 104 can be a static random-access memory (SRAM) die. The intermediate die 108 is a three-dimensional die and includes a BSPDN. In accordance with at least one embodiment of the present disclosure, the intermediate die 108 is a logic die. As mentioned above, such arrangements can be particularly useful, for example, for AI hardware applications.

The connection features 112 are arranged on an uppermost surface 111 of the intermediate die 108. In accordance with at least one embodiment of the present disclosure, the connection features 112 can include solder bumps and corresponding conductive pads on the top die 104 and the intermediate die 108. In an alternative embodiment, the connection features could include copper features to enable copper bonding or copper hybrid bonding between the top die 104 and the intermediate die 108. In accordance with at least one embodiment of the present disclosure, the intermediate die 108 can be considered to include the conductive pads and/or solder bumps of the connection features 112 that are arranged thereon.

As shown, the semiconductor device 100 further includes lower connection features 116 configured to physically and electrically connect the intermediate die 108 and an interposer or packaging substrate, which is not shown. In accordance with at least one embodiment of the present disclosure, the lower connection features 116 can include solder bumps and the corresponding conductive pads on the intermediate die 108 and the interposer or packaging substrate. In an alternative embodiment, the lower connection features could be copper features to enable copper hybrid bonding between the intermediate die 108 and the interposer or packaging substrate. Alternatively, the lower connection features could include a copper pillar with solder attached to the surface of the intermediate die 108. In accordance with at least one embodiment of the present disclosure, the intermediate die 108 can be considered to include the conductive pads, copper pillars, and/or solder bumps of the lower connection features 116 that are arranged thereon.

In accordance with embodiments of the present disclosure, the intermediate die 108 includes a wafer 122 having a frontside and a backside. Notably, in the illustration shown in FIG. 1, the intermediate die 108 has been flipped during processing. Accordingly, the frontside is arranged on the side of the wafer 122 that faces downwardly toward the bottom of the page, and the backside is arranged on the side of the wafer 122 that faces upwardly toward the top of the page. Descriptions of surfaces and orientations herein are with reference to the arrangement of the intermediate die 108 as shown in FIG. 1.

The intermediate die 108 further includes front end of line (FEOL) devices 120 arranged on the frontside of the wafer 122, frontside BEOL wiring 124 on the frontside of the wafer 122, and backside BEOL wiring 128 on the backside of the wafer. The wafer 122 can be considered to include the FEOL devices 120. More specifically, the frontside BEOL wiring 124 is included in a first dielectric material 109a that is arranged on and coupled to the frontside of the wafer 122, and the backside BEOL wiring 128 is included in a second dielectric material 109b that is arranged on and coupled to the backside of the wafer 122. In particular, the first dielectric material 109a is a frontside dielectric material including the frontside BEOL wiring 124 embedded therein, and the second dielectric material 109b is a backside dielectric material including the backside BEOL wiring 128 embedded therein.

The FEOL devices 120 can include, for example, transistors, capacitors, etc., which are electrically connected to the frontside BEOL wiring 124 and the backside BEOL wiring 128. The frontside BEOL wiring 124 includes relatively thin (or fine) lines and vias configured to provide signals to and among the FEOL devices 120. The backside BEOL wiring 128 includes relatively thick (or coarse) lines and vias configured to deliver power to the FEOL devices 120. Specifically, the backside BEOL wiring 128 includes a BSPDN configured to deliver power to the FEOL devices 120 from the backside of the intermediate die 108. As shown, the backside BEOL wiring 128 is in direct contact with the backside of the wafer 122 and is in direct contact with the connection features 112. Accordingly, the backside BEOL wiring 128 is electrically connected to the connection features 112. Additionally, the backside BEOL wiring 128 on the backside of the wafer 122 is electrically connected to the FEOL devices 120 on the frontside of the wafer 122 through nano through silicon vias (TSVs) (not shown) that are formed through the wafer 122.

The intermediate die 108 also includes through silicon vias (TSVs) 132a, 132b, and 132c, which are arranged in direct contact with the lower connection features 116 to conduct power therethrough from the interposer or packaging substrate, through the backside BEOL wiring 128, and to the FEOL devices 120. Accordingly, each of the TSVs 132a, 132b, and 132c is in direct contact with a corresponding lower connection feature 116 so as to enable electrical conduction therethrough. In particular, a lowermost surface 134 of each of the TSVs 132a, 132b, and 132c is substantially coplanar with a lowermost surface 110 of the intermediate die 108, which is also the lowermost surface of the first dielectric material 109a. Additionally, in the embodiment shown in FIG. 1, the lowermost surface 134 of each of the TSVs 132a, 132b, and 132c is substantially coplanar with an uppermost surface 118 of a corresponding lower connection feature 116.

As used herein, the term “coplanar” refers to two surfaces that lie in a common plane. In other words, two surfaces are coplanar if there exists a geometric plane that contains all the points of both of the surfaces. As used herein, the term “substantially” refers to the inclusion of deviations that do not affect the intended outcome of the term that it modifies. For example, surfaces that are substantially parallel include surfaces that are not exactly parallel but which do not deviate from being exactly parallel to an extent that affects the intended outcome of the parallel nature of the surfaces. Accordingly, two surfaces may be referred to as being substantially coplanar despite deviations from coplanarity, so long as those deviations do not impact the desired result of the coplanarity.

In this instance, the desired result of the coplanarity of the lowermost surface 134 of each of the TSVs 132a, 132b, and 132c and the uppermost surface 118 of a corresponding lower connection feature 116 is to facilitate the formation of a robust physical and electrical connection between the lower connection feature 116 and the TSVs 132a, 132b, and 132c by ensuring that contact is made evenly across the interface between the TSVs 132a, 132b, and 132c and the corresponding lower connection features 116.

In the embodiment shown, the TSV 132b extends from its lowermost surface 134 to its uppermost surface 135b. As shown, the uppermost surface 135b is substantially coplanar with an uppermost surface 111 of the intermediate die 108, which is also an uppermost surface of the second dielectric material 109b. Additionally, the uppermost surface 135b is substantially coplanar with a lowermost surface 114 of the connection feature 112b with which it is in direct contact. Accordingly, the TSV 132b is electrically connected to the connection feature 112b. As shown, the TSV 132b extends through the first dielectric material 109a, the wafer 122, and the second dielectric material 109b. In other words, the TSV 132b extends through the entire thickness of the intermediate die 108. The desired result of the coplanarity of the uppermost surface 135b of the TSV 132b and the lowermost surface 114 of the corresponding connection feature 112b is to facilitate the formation of a robust physical and electrical connection between the connection feature 112b and the TSV 132b by ensuring that contact is made evenly across the interface between the TSV 132b and the corresponding connection feature 112b.

To deliver power to the FEOL device 120b to which the TSV 132b is electrically connected, the power travels along power delivery pathway PDPb from the interposer or packaging substrate, through the lower connection feature 116b to which the TSV 132b is connected. The power then travels through the TSV 132b to the connection feature 112b to which the TSV 132b is connected. The power then travels through the connection feature 112b to the connected backside BEOL wiring 128b and to the corresponding FEOL device 120b. Accordingly, the power delivery pathway PDPb delivers power to the corresponding FEOL device 120b through the TSV 132b, the connection feature 112b, and the backside BEOL wiring 128b. Thus, the configuration and arrangement of the TSV 132b within the device 100 enables backside delivery of power from the interposer or packaging substrate to the FEOL device 120b without interfering with the frontside delivery of signal to the same FEOL device 120b.

In contrast to TSV 132b, the TSV 132a does not extend through the entire thickness of the intermediate die 108. Accordingly, the TSV 132a is also referred to herein as a shortened TSV. As shown, the shortened TSV 132a extends from its lowermost surface 134 to its uppermost surface 135a, which is electrically connected through nano-TSVs in the wafer 122 with the backside BEOL wiring 128a that is connected to the FEOL device 120a to which the TSV 132a is configured to deliver power. Accordingly, the uppermost surface 135a of the shortened TSV 132a is substantially coplanar with a lowermost surface of the wafer, which is also substantially coplanar with an uppermost surface of the first dielectric material 109a. In other words, the shortened TSV 132a extends through the first dielectric material 109a and is in direct contact with the wafer 122 through which the shortened TSV 132a is electrically connected with the backside BEOL wiring 128a embedded in the second dielectric material 109b.

Due to the location of the wafer 122 within the intermediate die 108, the uppermost surface 135a of the shortened TSV 132a is arranged within the thickness of the intermediate die 108 instead of being substantially coplanar with the uppermost surface 111 of the intermediate die 108. Thus, the shortened TSV 132a is shorter than the TSV 132b and the TSV 132c, which is substantially similar to the TSV 132b. In other words, the height Ha of the shortened TSV 132a is less than the height Hb of the TSV 132b.

To deliver power to the FEOL device 120a to which the shortened TSV 132a is electrically connected, the power travels along power delivery pathway PDPa from the interposer or packaging substrate, through the lower connection feature 116a to which the shortened TSV 132a is connected. The power then travels through the shortened TSV 132a to the backside BEOL wiring 128a and to the corresponding FEOL device 120a. Accordingly, the power delivery pathway PDPa delivers power to the corresponding FEOL device 120a through the TSV 132a and the backside BEOL wiring 128a. Notably, in contrast to the TSV 132b, the shortened TSV 132a does not deliver power directly to a corresponding connection feature 112. In other words, the shortened TSV 132a does not deliver power indirectly to the backside BEOL wiring 128a through a corresponding connection feature 112. Instead, the power delivery pathway PDPa of the shortened TSV 132a delivers power directly from the shortened TSV 132a to the corresponding backside BEOL wiring 128a. Accordingly, the PDPa is shorter than the PDPb.

Power loss from a source to a device is directly related to the distance that the power travels from the source to the device. Thus, the shorter power delivery pathway PDPa of the shortened TSV 132a, relative to the power delivery pathway PDPb of the TSV 132b, enables backside delivery of power from the interposer or packaging substrate to the FEOL device 120a without interfering with the frontside delivery of signal to the same FEOL device 120a and with less voltage loss than the power delivery pathway PDPb. Reducing voltage loss improves the energy efficiency of the device 100.

In accordance with at least one embodiment of the present disclosure, the intermediate die 108 can have a total thickness of 20 micrometers. In such embodiments, the TSVs 132b and 132c can be 3×20 TSVs (having a diameter of 3 micrometers and a height of 20 micrometers) to span the entire thickness of the intermediate die 108. In such embodiments, the TSV 132a can be, for example, a 3×12 TSV (having a diameter of 3 micrometers and a height of 12 micrometers) to span the thickness between the lowermost surface 110 of the intermediate die 108 and the lowermost surface of the wafer 122 within the intermediate die 108. In other words, the sizes of the TSVs are sufficient to span the corresponding thicknesses within the device 100. Thus, in accordance with alternative embodiments of the present disclosure, the TSVs can have different sizes that are sufficient to span the corresponding thicknesses within the device 100.

Notably, the device 100 includes a combination of non-shortened TSVs 132b and 132c and a shortened TSV 132a. The combination enables the maintenance of efficient power delivery to the top die 104 of the device 100 (for example through TSV 132b) and adds shortened power delivery pathways to improve the efficiency of power delivery to the device 120 of the intermediate die 108 (for example through TSV 132a). Embodiments of the present disclosure can have different numbers and combinations of non-shortened TSVs and shortened TSVs as is appropriate for the specific application of the device 100.

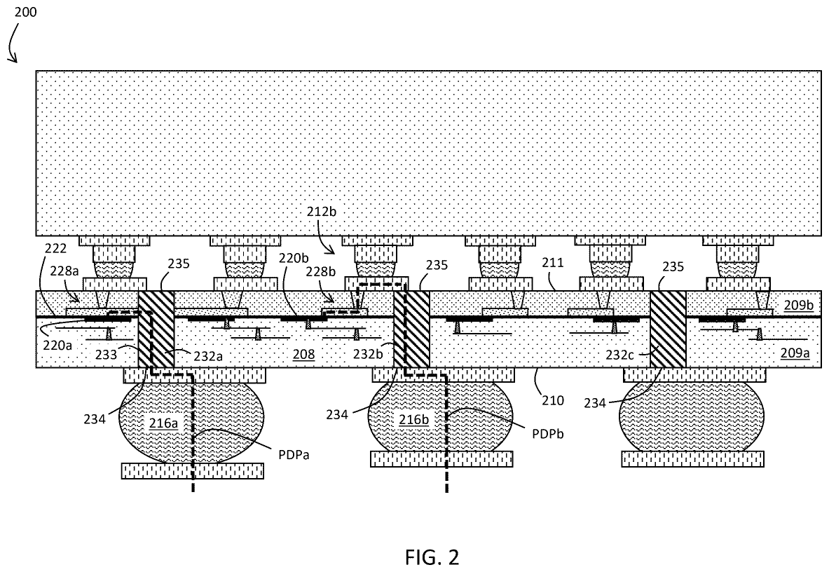

Turning now to FIG. 2, a cross-sectional schematic view of a semiconductor device 200 configured for power delivery to a device in a three-dimensional die including a BSPDN, in accordance with embodiments of the present disclosure, is illustrated. The device 200 is substantially similar to the device 100 described above with respect to FIG. 1. Accordingly, features and elements of the device 200 that are substantially similar to those of the device 100 will be similarly numbered, having the first digit of each reference number changed from a 1 to a 2. The device 200 differs from the device 100 in that the device 200 does not include any shortened TSVs.

In the embodiment shown in FIG. 2, the device 200 includes TSVs 232a, 232b, and 232c. Like the TSVs 132a, 132b, and 132c, the TSVs 232a, 232b, and 232c are arranged in the intermediate die 208 such that a lowermost surface 234 of each of the TSVs 232a, 232b, and 232c is substantially coplanar with the lowermost surface 210 of the intermediate die 208, which is also the lowermost surface of the first dielectric material 209a. Additionally, an uppermost surface 235 of each of the TSVs 232a, 232b, and 232c is substantially coplanar with the uppermost surface 211 of the intermediate die 208, which is also the uppermost surface of the second dielectric material 209b. Accordingly, all of the TSVs 232a, 232b, and 232c have the same height, and all of the TSVs 232a, 232b, and 232c extend through the entire thickness of the intermediate die 208. In other words, each of the TSVs 232a, 232b, and 232c extends through the first dielectric material 209a, the wafer 222, and the second dielectric material 209b.

In the embodiment shown in FIG. 2, the TSV 232a includes side surfaces 233 that are substantially perpendicular to the uppermost surface 235 of the TSV 232a as well as being substantially perpendicular to the lowermost surface 234 of the TSV 232a. The TSV 232a is arranged such that the side surfaces 233 are in direct contact with the backside BEOL wiring 228a that is connected to the FEOL device 220a to which the TSV 232a delivers power. Accordingly, as shown, the TSV 232a is in direct contact with the backside BEOL wiring 228a at the uppermost surface of the wafer 222 because the backside BEOL wiring 228 is formed directly on the uppermost surface of the wafer 222 and because the TSV 232a is formed through the thickness of the wafer 222.

As with the power delivery pathway PDPa of the device 100, the power delivery pathway PDPa of the device 200 that delivers power from the interposer or packaging substrate to the FEOL device 220a is shorter than the power delivery pathway PDPb that delivers power to the FEOL device 220b, even though, in contrast to the TSV 132a of the device 100, the TSV 232a is the same height as the TSV 232b.

More specifically, the power delivery pathway PDPb delivers power from the interposer or packaging substrate through the lower connection feature 216b to which the TSV 232b is connected. The power then travels through the TSV 232b to the connection feature 212b to which the TSV 232b is connected. The power then travels through the connection feature 212b to the connected backside BEOL wiring 228b and to the corresponding FEOL device 220b. Thus, the configuration and arrangement of the TSV 232b within the device 200 enables backside delivery of power from the interposer or packaging substrate to the FEOL device 220b without interfering with the frontside delivery of signal to the same FEOL device 220b.

In contrast, the shorter power delivery pathway PDPa delivers power from the interposer or packaging substrate through the lower connection feature 216a to which the TSV 232a is connected. The power then travels through the TSV 232a to the backside BEOL wiring 228a, which is in direct contact with the side surfaces 233 of the TSV 232a, and to the corresponding FEOL device 220a. Thus, the shorter power delivery pathway PDPa of the TSV 232a, relative to the power delivery pathway PDPb of the TSV 232b, enables backside delivery of power from the interposer or packaging substrate to the FEOL device 220a without interfering with the frontside delivery of signal to the same FEOL device 220a and with less voltage loss than the power delivery pathway PDPb. Reducing voltage loss improves the energy efficiency of the device 200.

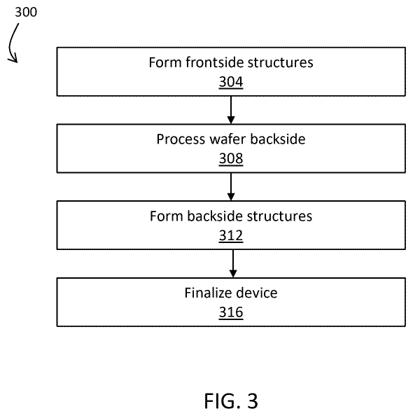

FIG. 3 illustrates a flowchart of a method 300 for forming a semiconductor device, in accordance with embodiments of the present disclosure. In particular, the method 300, or portion(s) thereof, can be used to form an intermediate die (such as, for example, the intermediate die 108 described above with reference to FIG. 1) that can be used in a semiconductor device (such as, for example, the device 100 described above with reference to FIG. 1) that is configured for backside power delivery to a device in a three-dimensional die.

As described in further detail below, the method 300 includes: operation 304, wherein structures are formed on a frontside of a wafer; operation 308, wherein a backside of the wafer is processed; operation 312, wherein structures are formed on the backside of the wafer; and operation 316, wherein the device is finalized. The performance of any of the operations of the method 300 may include the performance of a number of sub-operations.

More specifically, the performance of operation 304 includes forming a frontside dielectric material on the frontside of a wafer that has associated FEOL devices formed thereon. The performance of operation 304 further includes forming BEOL wiring in the frontside dielectric material. In other words, the performance of operation 304 includes forming frontside wiring in a first dielectric material on a frontside of a wafer such that the frontside wiring is electrically connected to FEOL devices on the frontside of the wafer. In accordance with embodiments of the present disclosure, the performance of operation 304 further includes forming a shortened TSV in the frontside dielectric material on the frontside of the silicon wafer such that the shortened TSV does not interfere with the frontside BEOL wiring.

In some embodiments, the formation of the shortened TSV can include forming the shortened TSV to the frontside surface of the wafer, but not through the wafer. In such embodiments, nano-TSVs can be utilized to establish electrical connection for the shortened TSV through the wafer. In alternative embodiments, the formation of the shortened TSV can include forming the shortened TSV through the wafer. In such embodiments, the uppermost surface of the shortened TSV is substantially coplanar with an uppermost surface of the wafer.

In accordance with embodiments of the present disclosure, forming the shortened TSV in the frontside dielectric material on the frontside of the silicon wafer can include selectively etching the frontside dielectric material to form a shortened TSV opening. Such embodiments can further include insulating the shortened TSV opening and/or forming a diffusion barrier in the shortened TSV opening. Such a diffusion barrier can be, for example TaN or Ta or a combination thereof. Such embodiments can further include performing Cu seed deposition, followed by Cu plating to form the shortened TSV in the insulated/lined shortened TSV opening. Such embodiments can further include performing CMP on the resulting device such that the shortened TSV is substantially coplanar with the frontside dielectric material surrounding the frontside BEOL wiring.

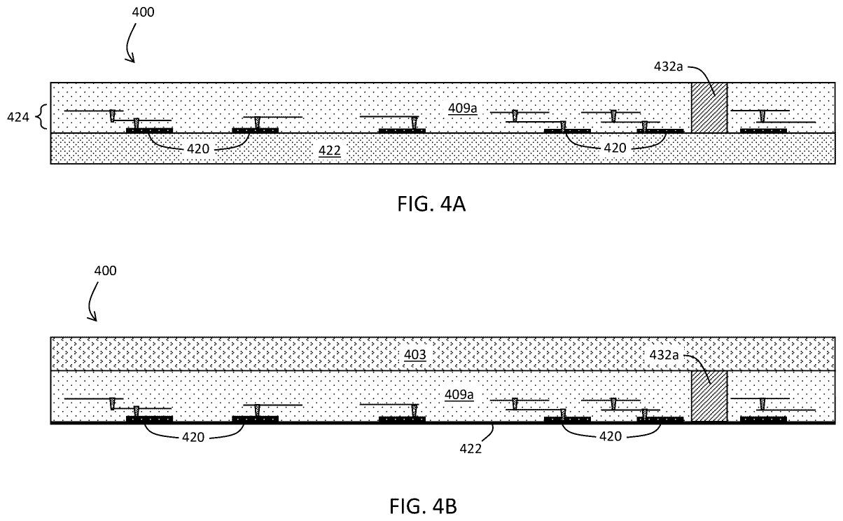

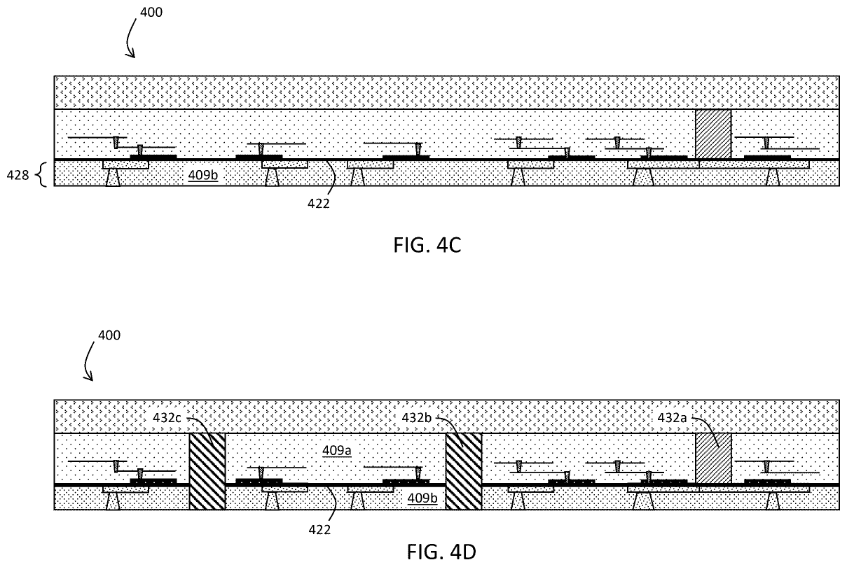

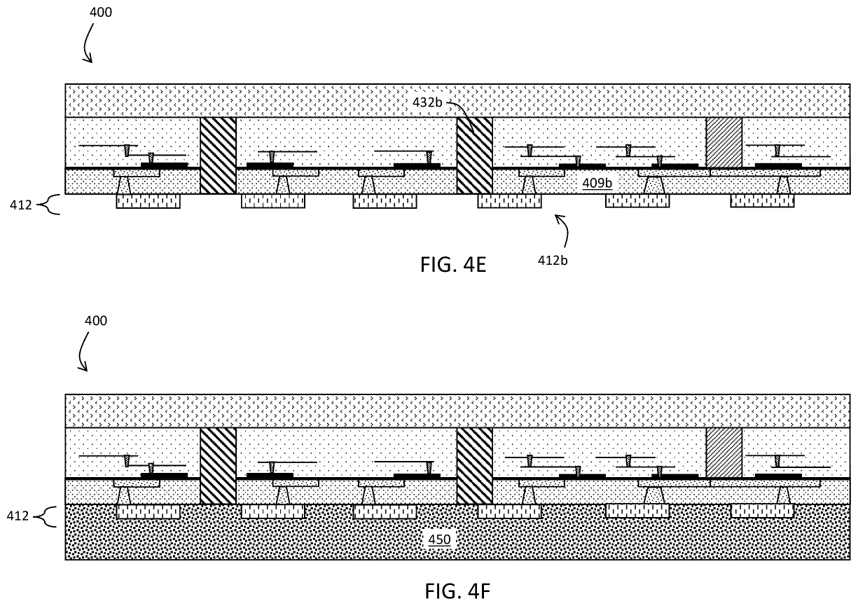

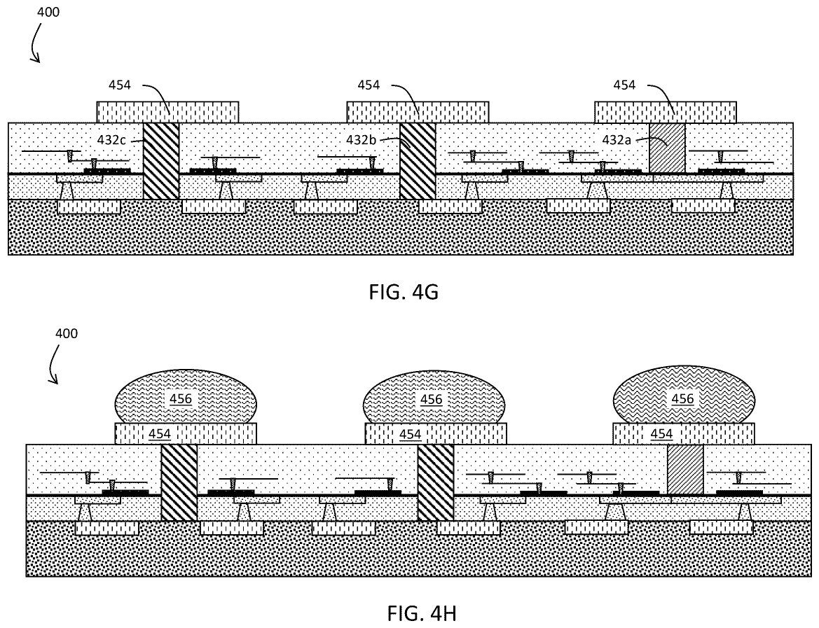

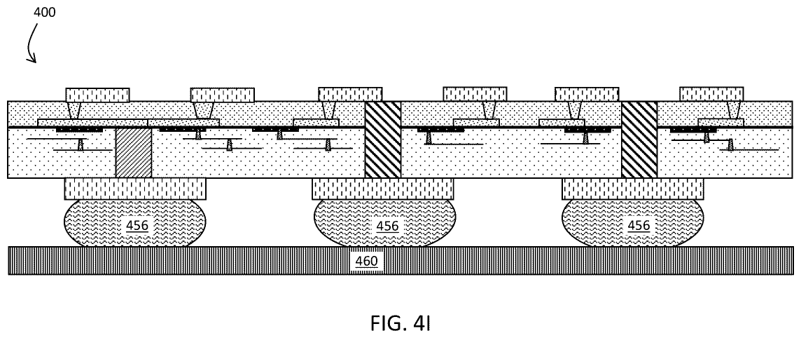

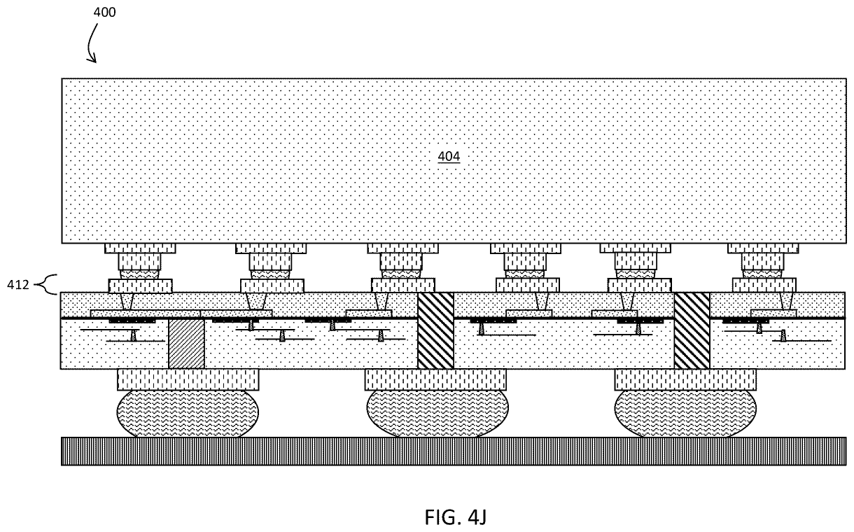

FIG. 4A illustrates an example device 400 following the performance of this portion of operation 304. As shown, the device 400 includes a wafer 422 having a number of FEOL devices 420 formed on the frontside thereof. The device 400 further includes frontside BEOL wiring 424 formed in a first dielectric material, also referred to herein as frontside dielectric material 409a, and configured to enable signal delivery to the FEOL devices 420. The device 400 further includes a shortened TSV 432a that is formed in the frontside dielectric material 409a on the frontside of the wafer 422 such that the shortened TSV 409a is in direct contact with the wafer 422. In other words, the shortened TSV 432a extends through the entire thickness of the frontside dielectric material on the frontside of the wafer 422.

Returning to FIG. 3, following the performance of operation 304, the method 300 proceeds with operation 308, wherein the backside of the wafer is processed. In accordance with embodiments of the present disclosure, the performance of operation 308 includes attaching a temporary handler to the frontside of the device. The performance of operation 308 further includes thinning the wafer from the backside of the wafer. Thus, the performance of operation 308 further includes thinning the backside of the wafer, which can include, for example, grinding, polishing, and/or Si RIE as needed. The backside of the wafer is thinned until the wafer has a thickness of approximately 50-100 nanometers. The performance of operation 308 further includes forming nano-TSVs through the wafer from the backside of the wafer. The nano-TSVs have a height that is the same as the thickness of the thinned wafer. Accordingly, the nano-TSVs have a height of, for example, approximately 50-100 nanometers. As a result, in the performance of the method 300, the shortened TSV has been formed through the first dielectric material and electrically connected to the backside wiring through nano-TSVs.

FIG. 4B illustrates an example device 400 following the performance of this portion of operation 308. As shown, the device 400 includes a temporary handler 403 attached to the frontside of the device 400. Accordingly, the temporary handler 403 is in direct contact with the frontside dielectric material 409a and the shortened TSV 432a. As shown, the wafer 422 has been thinned from the backside of the device 400 such that it is approximately 50-100 nanometers thick. Although not visible due to the scale of the drawings, the device 400 further includes nano-TSVs that are formed so as to extend through the thinned wafer 422 to enable electrical connections with the FEOL devices 420 therethrough.

Returning to FIG. 3, following the performance of operation 308, the method 300 proceeds with the performance of operation 312, wherein structures are formed on the backside of the wafer. More specifically, the performance of operation 312 includes forming a backside dielectric material on the backside of the wafer. The performance of operation 312 further includes forming BEOL wiring in the backside dielectric material as well as providing connections from the backside BEOL wiring to the nano-TSVs, which enable connection through the wafer to the FEOL devices. In other words, the performance of operation 312 includes forming backside wiring in a second dielectric material on the backside of the thinned wafer such that the backside wiring is electrically connected to the FEOL devices.

FIG. 4C illustrates an example device 400 following the performance of this portion of operation 312. As shown, the device 400 includes a second dielectric material, referred to herein as backside dielectric material 409b, and BEOL wiring 428 formed in the backside dielectric material 409b and in direct contact with the backside of the wafer 222.

In accordance with embodiments of the present disclosure, the performance of operation 312 further includes forming TSVs from the backside of the device. In particular, the TSVs are formed through the backside dielectric material, the wafer, and the frontside dielectric material. Formation of the TSVs includes the performance of operations substantially similar to those described above with respect to the formation of the shortened TSV in the performance of operation 304.

FIG. 4D illustrates an example device 400 following the performance of this portion of operation 312. As shown, the device 400 includes TSVs 432b and 432c that extend through the backside dielectric material 409b, through the wafer 422, and through the frontside dielectric material 409a. Accordingly, as shown, the TSVs 432b and 432c are longer than shortened TSV 432a.

Returning to FIG. 3, following the performance of operation 312, the method 300 proceeds with the performance of operation 316, wherein the device is finalized. More specifically, in accordance with some embodiments of the present disclosure, the performance of operation 316 can include forming connection features configured to enable the connection of the device with other components. In accordance with at least one embodiment of the present disclosure, the performance of operation 316 can include forming conductive pads, such as landing pads, with under-bump metallurgy to enable soldering the device to other components.

FIG. 4E illustrates an example device 400 following the performance of this portion of operation 316. As shown, the device 400 includes connection features 412 formed on the backside of the device 400 and configured to enable electrical connection of the device 400 with other semiconductor devices in an IC. In the embodiment shown, the connection features 412 include landing pads with under bump metallurgy, ready to receive a top die thereon. However, in alternative embodiments, different connection features can be formed which enable different methods of connecting the device to other components. As shown, the connection features 412 are formed in direct contact with the backside dielectric material 409b. Additionally, the connection feature 412b is formed in direct contact with corresponding TSV 432b to enable a power delivery pathway to be formed that is configured to deliver power therethrough.

In accordance with embodiments of the present disclosure, the performance of operation 316 can further include attaching a second carrier to the backside of the device to support the structure.

FIG. 4F illustrates an example device 400 following the performance of this portion of operation 316. As shown, the device 400 includes a second carrier 450 formed on the backside of the device 400 surrounding the connection features 412 and providing physical support to the structure of the device 400.

In accordance with embodiments of the present disclosure, the performance of operation 316 can further include releasing the temporary handler and forming conductive pads, such as capture pads, on the frontside of the device. Following the performance of this portion of operation 316, the top side of the device is configured to enable a top die with C4s to be joined in a “die to wafer” format, followed by underfill and encapsulation, resulting in structural stability before final dicing.

FIG. 4G illustrates an example device 400 following the performance of this portion of operation 316. As shown, the device 400 no longer includes the temporary handler 403 (labeled in FIG. 4B), which has been released from the frontside of the device 400. Furthermore, the device 400 includes capture pads 454 formed on the frontside of the device 400. The capture pads 454 are configured to enable the formation of lower connection features (such as, for example, lower connection features substantially similar to lower connection features 116 described above with respect to FIG. 1) when the device 400 is connected to other components and to enable power delivery pathways to be formed that are configured to deliver power therethrough. Accordingly, each of the capture pads 454 is formed in direct contact with a corresponding TSV 432a, 432b, or 432c.

In accordance with embodiments of the present disclosure, the performance of operation 316 can further include forming C4 bumps to enable joining the device with an interposer or packaging substrate. For embodiments in which the device will be joined to an interposer or packaging substrate, underfilling may be performed after joining.

FIG. 4H illustrates an example device 400 following the performance of this portion of operation 316. As shown, the device 400 includes a C4 bump 456 formed on each of the capture pads 454.

In accordance with embodiments of the present disclosure, the performance of operation 316 can further include joining the device with an interposer, packaging substrate, or temporary carrier. For embodiments in which the device is joined with a temporary carrier, an adhesive or other bonding agent will be used to join the device. For embodiments in which the device is joined with an interposer or packaging substrate, underfilling may be done after joining.

In accordance with embodiments of the present disclosure, the performance of operation 316 can further include releasing the second carrier and cleaning the surface. The device can also be flipped at this time to be arranged such that the connection features are arranged facing upwardly to enable connection with a top die and such that the joined interposer or packaging substrate is arranged facing downwardly.

FIG. 4I illustrates an example device 400 following the performance of this portion of operation 316. As shown, the device 400 includes an interposer, packaging substrate, or temporary carrier 460 coupled to the C4s 456. The device 400 also lacks the second carrier 450 (labeled in FIG. 4F).

In accordance with embodiments of the present disclosure, the performance of operation 316 can further include joining a top die with the C4s of the device. An underfill or overmolding process (as appropriate) can then be performed on the device. For embodiments in which a temporary carrier was utilized, a release step is performed. Finally, the device can be subjected to dicing and joining the die stack to the interposer or final substrate. Following the performance of this portion of operation 316, the device is substantially similar to the device 100 shown and described above with respect to FIG. 1.

FIG. 4J illustrates an example device 400 following the performance of this portion of operation 316. As shown, the device 400 includes a top die 404 coupled to the connection features 412. As shown, the device 400 is substantially similar to the device 100 shown and described above with respect to FIG. 1.

In accordance with alternative embodiments of the present disclosure, the method 300 can be used to form an intermediate die similar to the intermediate die 208 that can be used in the device 200 described above with reference to FIG. 2. In such embodiments, the performance of operation 304 (wherein structures are formed on a frontside of a wafer) does not include forming a shortened TSV. Instead, in such embodiments, all TSVs are formed in the performance of operation 312 (wherein structures are formed on the backside of the wafer).

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A semiconductor device, comprising:
a wafer having a frontside and a backside and a plurality of front end of line devices arranged on the frontside;
a first dielectric material coupled to the frontside of the wafer and including frontside wiring embedded therein that is electrically connected to the front end of line devices;
a second dielectric material coupled to the backside of the wafer and including backside wiring embedded therein that is electrically connected to the front end of line devices;
a first via extending through the first dielectric material and electrically connected with the backside wiring such that a first power delivery pathway delivers power to a first front end of line device through the first via and the backside wiring; and
a second via extending through the first dielectric material and electrically connected with the backside wiring such that a second power delivery pathway delivers power to a second front end of line device through the second via and the backside wiring, wherein:
the first power delivery pathway is shorter than the second power delivery pathway.

2. The semiconductor device of claim 1, wherein:
a lowermost surface of the first via is substantially coplanar with a lowermost surface of the first dielectric material.

3. The semiconductor device of claim 2, wherein:
an uppermost surface of the first via is substantially coplanar with an uppermost surface of the first dielectric material.

4. The semiconductor device of claim 3, wherein:
the uppermost surface of the first via is in direct contact with the frontside of the wafer.

5. The semiconductor device of claim 2, wherein:
the first via extends through the wafer and the second dielectric material; and
an uppermost surface of the first via is substantially coplanar with an uppermost surface of the second dielectric material.

6. The semiconductor device of claim 5, wherein:
a side surface of the first via is substantially perpendicular to the uppermost surface of the first via; and
the side surface is in direct contact with the backside wiring.

7. The semiconductor device of claim 1, wherein:
the second via extends through the wafer and the second dielectric material.

8. The semiconductor device of claim 7, wherein:
a lowermost surface of the second via is substantially coplanar with a lowermost surface of the first dielectric material; and
an uppermost surface of the second via is substantially coplanar with an uppermost surface of the second dielectric material.

9. The semiconductor device of claim 1, wherein:
the first power delivery pathway does not extend to an uppermost surface of the second dielectric material.

10. A semiconductor device, comprising:
a wafer having a frontside and a backside and a plurality of front end of line devices arranged on the frontside;
a first dielectric material coupled to the frontside of the wafer and including frontside wiring embedded therein that is electrically connected to the front end of line devices;
a second dielectric material coupled to the backside of the wafer and including backside wiring embedded therein that is electrically connected to the front end of line devices;
a first via extending through the first dielectric material and electrically connected with the backside wiring; and
a second via extending through the first dielectric material, the wafer, and the second dielectric material, wherein:
the first via contacts the backside wiring nearer to the first dielectric material than does the second via.

11. The semiconductor device of claim 10, further comprising:
a connection feature arranged on an uppermost surface of the second dielectric material and electrically connected to the second via and to the backside wiring.

12. The semiconductor device of claim 11, wherein:
a first power delivery pathway delivers power to a first front end of line device through the first via and the backside wiring,
a second power delivery pathway delivers power to a second front end of line device through the second via, the connection feature, and the backside wiring, and
the first power delivery pathway is shorter than the second power delivery pathway.

13. The semiconductor device of claim 11, wherein:
an uppermost surface of the first via is in direct contact with the frontside of the wafer.

14. The semiconductor device of claim 11, wherein:
an uppermost surface of the first via is substantially coplanar with an uppermost surface of the second dielectric material.

15. The semiconductor device of claim 14, wherein:
a side surface of the first via is substantially perpendicular to the uppermost surface of the first via, and
the side surface is in direct contact with the backside wiring.

16. A method of forming a semiconductor device, the method comprising:
forming frontside wiring in a first dielectric material on a frontside of a wafer such that the frontside wiring is electrically connected to front end of line devices on the frontside of the wafer;
thinning the wafer from a backside of the wafer;
forming backside wiring in a second dielectric material on the backside of the thinned wafer such that the backside wiring is electrically connected to the front end of line devices; and
forming a first via through the first dielectric material and electrically connected with the backside wiring.

17. The method of claim 16, wherein:
forming the first via includes forming the first via such that an uppermost surface of the first via is substantially coplanar with the frontside of the wafer, and
the first via is formed before forming the backside wiring.

18. The method of claim 16, wherein:
forming the first via includes forming the first via such that an uppermost surface of the first via is substantially coplanar with an uppermost surface of the second dielectric material and such that a side surface of the first via is substantially perpendicular to the uppermost surface of the first via and is in direct contact with the backside wiring, and
the first via is formed after forming the backside wiring.

19. The method of claim 16, further comprising:
forming a second via through the first dielectric material, the wafer, and the second dielectric material such that the second via is not in direct contact with the backside wiring.

20. The method of claim 19, further comprising:
forming a connection feature in direct contact with the second via and with the backside wiring.
